(19) United States
(12) Patent Application Publication
(10) Pub. No.: US 2012/0299162 A1
(43) Pub. Date: Nov. 29, 2012

(54) BARRIER FILM FOR ELECTRONIC DEVICE, METHOD OF MANUFACTURE THEREOF, AND ARTICLES INCLUDING THE SAME

(75) Inventors: Kenichi Nagayama, Yokohama-si (JP); Yukika Yamada, Yokohama-si (JP); Tadao Yagi, Yokohama-si (JP)

(73) Assignee: SAMSUNG ELECTRONICS CO. LTD., Suwon-si (KR)

(21) Appl. No.: 13/478,891

(22) Filed: May 23, 2012

(30) Foreign Application Priority Data
May 23, 2011 (JP) 2011-114527
Mar. 6, 2012 (KR) 10-2012-0022877

(51) Int. Cl. H01L 23/29; H01L 21/02

(52) U.S. Cl. 257/637; 438/763; 257/E23.002; 257/E21.002

(57) ABSTRACT

A barrier film for an electronic device, the barrier film including: a resin film; a layer-by-layer stack portion including a tabular inorganic particle layer and a binder layer which are alternately disposed on the resin film and are oppositely charged; and a filling portion that fills a defect portion of the tabular inorganic particle layer wherein the defect portion is a portion of the tabular inorganic particle layer where a tabular inorganic particle of the tabular inorganic particle layer is not present.

This application claims priority to and the benefit of Japanese Patent Application No. 10-2011-0114527, filed on May 23, 2011, and Korean Patent Application No. 10-2012-022877, filed on Mar. 6, 2012, and all the benefits accruing therefrom under 35 U.S.C. §119, the contents of which are incorporated herein in their entirety by reference.

### BACKGROUND

1. Field

The present disclosure relates to a barrier film for an electronic device, methods of manufacture thereof, and articles including the barrier film.

2. Description of the Related Art

A barrier film includes a barrier layer on a resin film. Typically, barrier films are used to package food products. Now, they are further used as flexible substrates for electronic devices. However, there is a need to considerably improve the performance of barrier films for electronic devices.

US 2004/053037 (hereinafter, referred to as ‘patent literature 1’) discloses a barrier film. (All references cited herein are incorporated by reference in their entirety.) The barrier film of patent literature 1 is formed by stacking a clay layer formed from clay particles and a cationic resin by layer-by-layer adsorption. However, in the barrier film disclosed in patent literature 1, the density (adsorption density) of clay particles is non-uniform (e.g., unstable) and thus, many defects where the clay particles are not adsorbed to the resin film are formed. The defects are passages where a gas, such as water vapor, can transport. Thus, the respective clay layers of the barrier film of patent literature 1 may have insufficient barrier performance. This problem can be overcome by increasing the number of clay layers. However, increasing the number of clay layers to provide sufficient barrier performance complicates the manufacturing process and results in a barrier film having unsuitable thickness. Thus there remains a need for an improved barrier film and method of manufacture thereof.

### SUMMARY

Provided is a novel and improved barrier film for an electronic device, which has improved barrier performance.

Additional aspects, features, and advantages will be set forth in part in the description which follows and, in part, will be apparent from the description.

According to an aspect, a barrier film for an electronic device includes: a resin film; a layer-by-layer stack portion including a tabular inorganic particle layer and a binder layer which are alternately disposed on the resin film and are oppositely charged; and a filling portion that fills a defect portion of the tabular inorganic particle layer wherein the defect portion is a portion of the tabular inorganic particle layer where a tabular inorganic particle of the tabular inorganic particle layer is not present.

In the barrier film, the defect portion may be filled with the filling portion. Due to the filling portion, gas permeation through the defect portion may be prevented. Accordingly, barrier performance of the barrier film may be improved.

The filling portion may include a metal oxide. Due to the inclusion of the metal oxide, gas permeation through the defect portion of the barrier film may be further prevented.

The metal oxide may include at least one metal selected from vanadium, tungsten, and molybdenum. Due to the inclusion of the metal oxide, gas permeation through the defect portion of the barrier film may be further prevented.

The metal oxide may include phosphorus. Due to the inclusion of the phosphorous, gas permeation through the defect portion of the barrier film may be further prevented.

The tabular inorganic particle included in the tabular inorganic particle layer may be negatively charged and the binder layer may be positively charged. By having the layers oppositely charged, the respective layers of the barrier film are strongly adsorbed to each other due to a coulombic force. Thus, the barrier performance may be further enhanced.

The tabular inorganic particle may be an exfoliation product of at least one selected from a clay mineral and zirconium phosphate. Because the tabular inorganic particle substantially or effectively prevents the gas permeation, the barrier performance of the barrier film may be further enhanced.

The clay mineral may include at least one selected from mica, bermiculite, montmorillonite, iron montmorillonite, beidellite, saponite, hectorite, and stevensite. Because the tabular inorganic particle substantially or effectively prevents the gas permeation, the barrier performance of the barrier film may be further enhanced.

The clay mineral may include montmorillonite. Montmorillonite is easily layer-separated, and thus, from this aspect, the tabular inorganic particle may be easily formed.

The tabular inorganic particle may be an exfoliation product of zirconium phosphate. Zirconium phosphate is easily layer-separated, and thus, from this aspect, the tabular inorganic particle may be easily formed.

The barrier film may further include an adsorption layer that is disposed on the resin film and adsorbs the resin film to the layer-by-layer stack portion. By providing an adsorption layer, the layer-by-layer stack portion may be more strongly adsorbed to the resin film, and thus, the barrier performance of the barrier film may be further enhanced. Also, because the adsorption layer substantially or effectively prevents the gas permeation, the barrier performance of the barrier film may be further enhanced.

The adsorption layer may include at least one selected from silica and alumina. By providing the adsorption layer, the layer-by-layer stack portion may be more strongly adsorbed to the resin film, and thus, the barrier performance of the barrier film may be further enhanced.

The adsorption layer may have a charge opposite to that of a layer of the layer-by-layer stack portion adsorbed on to the adsorption layer. By providing the adsorption layer, the layer-by-layer stack portion may be more strongly adsorbed to the resin film, and thus, the barrier performance of the barrier film may be further enhanced.

The adsorption layer may be charged using a silane coupling agent. Due to the use of the silane coupling agent, the adsorption layer may be more strongly charged.

Also disclosed is a method of manufacturing a barrier film for an electronic device, the method including: providing a resin film having a charged surface; disposing a charged tabular inorganic particle on the resin film to form a tabular inorganic particle layer; contacting the tabular inorganic particle layer with a solution including at least one selected from a metal and a metal oxide to fill a defect of the tabular inorganic particle layer and form a filled tabular inorganic particle layer; and contacting the filled tabular inorganic particle layer with a charged binder particle to form a binder layer on the filled tabular inorganic particle layer and manufacture the barrier film.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view illustrating an embodiment of a barrier film for an electronic device;

FIGS. 2A and 2B are each a schematic illustration of an embodiment of a process for forming (e.g., filling) a filling portion where a tabular inorganic particle is not present;

FIG. 3 is a graph of potential (Volts) versus pH and is a Pourbaix diagram of tungsten; and

FIG. 4 is a cross-sectional view illustrating an embodiment of a method of manufacturing the barrier film of FIG. 1.

### DETAILED DESCRIPTION

Hereinafter, an embodiment of a barrier film for an electronic device is described in further detail with reference to the attaching drawings. This invention may, however, be embodied in many different forms, and should not be construed as limited to the embodiments set forth herein. Rather, these embodiments are provided so that this disclosure will be thorough and complete, and will fully convey the scope of the invention to those skilled in the art. In the drawings, like reference numerals denote like elements or portions of like elements.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” It will be further understood that the terms “comprises” and/or “comprising,” or “includes” and/or “including” when used in this specification, specify the presence of stated features, regions, integers, steps, operations, elements, processes, and/or components, but do not preclude the presence or addition of one or more other features, regions, integers, steps, operations, elements, components, processes and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, problems of a typical barrier film are described and then, an embodiment of the barrier film, e.g., barrier film 1, is disclosed in further detail with reference to the drawings.

### Problems of a Typical Barrier Film

In a flexible substrate for an electronic device, a barrier film has a barrier layer on a resin film. Typically, barrier films are used to package food products. For their use in electronic devices, it would be desirable to considerably improve barrier performance. For example, in the case of an organic electroluminescent device, which is an all solid-state light-emitting device known as being suitable for a flexible display, a barrier having a water vapor transmission rate (WVTR) of less than about 1·10⁻⁶ g/m²/day would be desirable.

Various barrier films satisfying such a high performance have been introduced by many companies. For example, US Vitex Corporation discloses a barrier film including a layer-by-layer stack structure of a resin film and an alumina layer. According to Vitex Corporation, the barrier film has performance suitable for an organic light-emitting device. Also, a barrier film having a WVTR of 0.05 g/m²/day was announced by Mitzbishi Resin Co., Ltd. on Feb. 20, 2008.

Following the introduction of these two technologies, many high-performance barrier films were formed using a vacuum process. The vacuum process is, briefly, a process of attaching a barrier film forming material onto a film substrate placed in a vacuum chamber. The vacuum process has a big vacuum chamber and thus, installation cost is high. Also, the vacuum process has high operating cost for maintaining the vacuum chamber, and thus, the manufacturing cost of the barrier film has increased. Also, the vacuum process provides a barrier film having low step coverage, and thus, pin holes are highly likely to occur due to impurities on the film substrate.

Also, as a method of forming a barrier film, a film formation method using a wet process is known. This film formation method does not have such problems of the vacuum process, and thus, a barrier film is formed with fewer pin holes and at lower cost. In the wet process, a sol-gel method or a method using clay particles that do not allow the gas permeation are used. A method of forming a barrier film using these methods is disclosed in, in addition to the patent literature 1, JP 2007-22075 (herein referred to as reference literature 1), and JP 2003-41153 (herein referred to as reference literature 2). The technology and problems thereof disclosed in the patent literature 1 are already described above.

Reference literature 1 discloses a barrier film in which a clay layer formed from clay particles (inorganic layered compound particles which are described below), and an inorganic layer formed using a sol-gel method, are alternately disposed. According to the technology disclosed in reference literature 1, the clay layer is formed by standing (i.e., without agitation) a dispersion in which clay particles are dispersed. However, the clay layer formed as described above has a low adhesion force with other layers, such as the inorganic layer. Also, because the clay layer is formed by only depositing clay particles, a bond between clay particles inside the clay layer is very weak. For example, once water permeates into the clay layer through the inorganic layer, water molecules may permeate into clay particles and thus, the clay layer expands and thus barrier performance of the barrier film are substantially decreased. This may be prevented by lowering a WVPR of the inorganic layer. In this case, however, the inorganic layer is calcined at high temperature (about 100 to about 500° C.), which makes the manufacturing of such a barrier layer complicated.

Reference literature 2 discloses a barrier film formed from a mixture of a sol-gel material and clay particles. In this technology, the clay particles are dispersed in the sol-gel material at a high concentration thereof to increase the barrier performance of the barrier film. An extent of increase in barrier performance of the barrier film when a layered compound, such as a clay, is dispersed in the sol-gel material is exemplarily calculated in “Pnanocomposite=Barrier Enhancement: Tortuous Path,” L. E. Neilson, J. MACROMOL. SCI. (CHEM.), A1(5), 929-942 (1967). According to the calculation method of Neilson et al., for example, when clay particles having a diameter of 1 μm and a thickness of 1 nm are used, to provide a decrease of two orders of magnitude in a WVTR of the sol-gel material to be mixed with the clay particles, that is, a WVTR of the barrier film, about 20 mass % of clay particles, based on the total mass of the barrier film, should be dispersed in the sol-gel material. A dispersion in which very planar particles, such as clay particles, are dispersed in the sol-gel material is thixotropic, and thus, during standing, the dispersion may have very high viscosity. Due to such a high viscosity, dispersing 20 mass % of clay particles in the sol-gel material is very difficult. Also, even when the clay particles are able to be dispersed in the sol-gel material with such a high concentration, due to the high viscosity of the dispersion, it is difficult to coat the dispersion to provide a film.

The disclosed barrier film for an electronic device solves such problems. Hereinafter, an embodiment of the barrier film for an electronic device is described in further detail.

### Structure of the Barrier Film

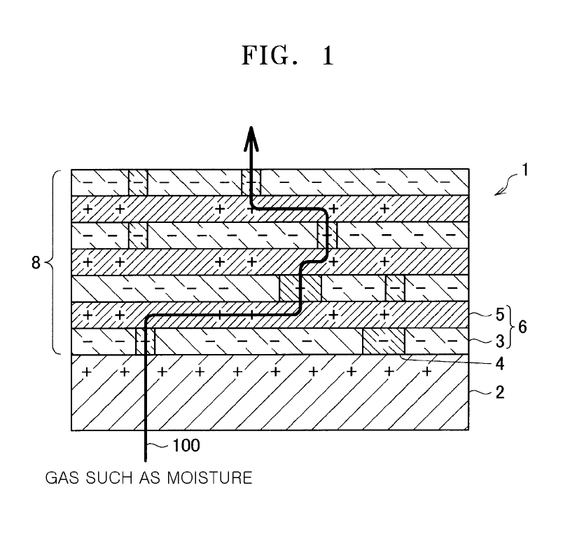

First, the structure of an embodiment of the barrier film is described in further detail with reference to FIG. 1.

A barrier film 1 includes a resin film 2, and a layer-by-layer stack portion 8 in which a tabular inorganic particle layer 3 and a binder layer 5 are alternately disposed. Also, hereinafter, a film formed in the procedure of forming the barrier film 1, that is, a film in which at least one of the tabular inorganic particle layer 3 and the binder layer 5 is disposed on the surface of the resin film 2, is referred to as an intermediate film.

### Structure of Resin Film

First, an embodiment of the structure of the resin film 2 is disclosed in further detail. The resin film 2 may comprise any resin, e.g., a polymer that is suitable for the intended use of the barrier film. The resin film 2 may comprise an epoxy, ethylene propylene diene rubber (EPR), ethylene propylene diene monomer rubber (EPDM), polyacetal, polyacrylamide, polyacrylic such as polyacrylic acid, polyacrylonitrile, polyamide including polyamideimide, polyarylene ether, polyarylene sulfide, polyarylene sulfone, polybenzoxazole, polybenzothiazole, polybutadiene and a copolymer thereof, polycarbonate, polycarbonate ester, polyether ketone, polyether ether ketone, polyether ketone ketone, polyethersulfone, polyester, polyimide such as polyetherimide, polyisoprene and a copolymer thereof, polyolefin such a polyethylene and a copolymer thereof, polypropylene and a copolymer thereof, polytetrafluoroethylene, polyphosphazene, poly(alkyl)(meth)acrylate, polystyrene and a copolymer thereof, a rubber-modified polystyrene such as acrylonitrile-butadiene-styrene (ABS), styrene-ethylene-butadiene (SEB), and methyl methacrylate-buadiene-styrene (MBS), polyoxadiazole, polysilazane, polysulfone, polysulfonamide, polyvinyl acetate, polyvinyl chloride, polyvinyl ester, polyvinyl ether, polyvinyl halides, polyvinyl nitrile, polyvinyl thioether, polyurea, polyurethane, polyethylene terephthalate, polyethylene naphthalate, or a silicone. A combination comprising at least one of the foregoing polymers can be used. A resin film 2 comprising at least one selected from polyethylene terephthalate (PET), polyethylene naphthalate (PEN), polyethersulfone (PES), polyimide (PI), is specifically mentioned. The resin film 2 may include these materials alone or in combination of two or more.

The surface of the resin film 2 may be either positively or negatively charged. In FIG. 1, the resin film 2 is positively charged. A method of charging of the surface of the resin film 2 is not particularly limited, and for example, a physical treatment (for example, a corona treatment, an ultraviolet (UV)/O₃ treatment, or the like), an electron beam (EB) treatment, a chemical treatment using a silane coupling agent, or the like, may be used. When the surface of the resin film 2 is subjected to a corona treatment, the surface of the resin film 2 may be negatively charged. Also, when the surface of the resin film 2 is treated with a silane coupling agent, the surface of the resin film 2 may be positively charged. Also, to increase the effect of the charging treatment, an adsorption layer may be formed on the resin film 2 and then the charging treatment performed on the adsorption layer. The adsorption layer may allow the resin film 2 to be strongly attached to the tabular inorganic particle layer 3 or the binder layer 5, and the adsorption layer may include a metal oxide, such as silica or alumina. Such metal oxides have a —OH group at a surface thereof in air, and thus, when treated with corona or UV/O₃, the surface may be strongly and uniformly charged. While not wanting to be bound by theory, it is understood that when the surface of the metal oxide is charged using the silane coupling agent, the silane coupling agent bonds to the —OH group at the surface of the metal oxide, so that the surface is strongly and uniformly charged.

According to the charge of the resin film 2, the tabular inorganic particle layer 3, and the binder layer 5, it is determined which is disposed on the resin film 2. For example, when the surface of the resin film 2 is positively charged and the tabular inorganic particle layer 3 is negatively charged, the tabular inorganic particle layer 3 is disposed on the resin film 2 and then, the binder layer 5 is disposed on the tabular inorganic particle layer 3.

### Structure of the Tabular Inorganic Particle Layer

Hereinafter, an embodiment of the tabular inorganic particle layer 3 of the barrier film 1 is described in further detail. The tabular inorganic particle layer 3 includes a tabular inorganic particle.

The tabular inorganic particle may be obtained by exfoliation (e.g., layer separation) of an inorganic layered compound, for example, a clay mineral, such as mica, bermiculite, montmorillonite, iron montmorillonite, beidellite, saponite, hectorite, and stevensite; zirconium phosphate; or a layered double hydroxide (LDH) compound. “Exfoliation” refers to separation of a layered material to provide a particle having a single layer or a plurality of layers.

In such inorganic layered compounds, a plurality of tabular inorganic particles that are either positively or negatively charged are stacked with an interlayer ion (for example, a sodium ion), which has a charge opposite to that of the tabular inorganic particle. To exfoliate layers of the inorganic layered compound, for example, a particle having a greater diameter than that of the interlayer ion may be inserted between the tabular inorganic particles. For example, a water molecule, a calcium ion, a tetrabutyl ammonium ion, or the like may be inserted between adjacent tabular inorganic particles. For example, the inorganic layered compound may be added to water, followed by stirring.

The tabular inorganic particle layer 3 may include a single type of tabular inorganic particle, or two or more different types of tabular inorganic particles having the same charge may be used.

Also, the ease of the layer separation may depend on the charge density of the inorganic layered compound. As an inorganic layered compound that is easily layer-separated, montmorillonite or zirconium phosphate may be used. Accordingly, such inorganic layered compounds have advantages in terms of the ease of layer separation.

A tabular inorganic particle has a substantially planar shape, and may include an inorganic material, such as a metal oxide. The tabular inorganic particle may substantially or effectively prevent a gas from permeating (e.g., transporting or diffusing) therethrough. Accordingly, by arranging the tabular inorganic particle to be parallel to other layers, the barrier performance of the barrier film, e.g., barrier film 1, may be improved.

The tabular inorganic particle may have, for example, a surface direction diameter of about 10 nm to about 10 μm, specifically about 20 nm to about 5 μm, more specifically about 40 nm to about 1 μm, and a thickness of about 1 to about 100 nm, specifically about 5 to about 80 nm, more specifically about 10 to about 60 nm. Also, the surface direction diameter is, for example, an arithmetic mean value of equivalent diameters of particles (a diameter under the assumption that a surface direction shape of a particle is circle), and the thickness is an arithmetic mean value of thicknesses of the respective particles. The surface direction diameter and thickness of the tabular inorganic particle may be measured by, for example, a scanning electron microscope (SEM), atomic force microscope (AFM), or a laser scattering particle size distribution analyzer.

Also, the tabular inorganic particle may be, as described above, either positively or negatively charged. For example, a tabular inorganic particle obtained from a clay mineral, such as mica, bermiculite, montmorillonite, iron montmorillonite, beidellite, saponite, hectorite, and stevensite, or zirconium phosphate may be negatively charged.

Also, a tabular inorganic particle obtained from the layered double hydroxide compound may be positively charged. That is, the layered double hydroxide compound may be represented by Formula 1 below:

[M²⁺₁₋ₓM³⁺ₓ(OH)₂]^{x+}[Aⁿ⁻_{x/n}.yH₂O]^{x-} (Formula 1)

wherein, in Formula 1, M²⁺ is a bivalent metal, M³⁺ is a trivalent metal, A is an anion, n is a valence of an anion, x is a real number satisfying 0<x<0.4, and y is a real number greater than 0. That is, the layered double hydroxide is a compound having a brucite structure, and a layered structure in which a negatively charged interlayer ion ([Aⁿ⁻_{x/n}.yH₂O]^{x-}) comprising an anion and interlayer water is located between positively charged tabular inorganic particle layers of the formula ([M²⁺₁₋ₓM³⁺ₓ(OH)₂]^{X+}).

The entire crystal of the layered double hydroxide compound is electrically neutral. A bivalent metal may be at least one selected from Mg, Mn, Fe, Co, Ni, Cu, Zn, and the like, and a trivalent metal may be at least one selected from Al, Fe, Cr, Co, In, and the like. Also, an anion may be at least one selected from OH⁻, F⁻, Cl⁻, NO₃⁻, SO₄²⁻, CO₃²⁻, Fe(CN)₆⁴⁻, CH₃COO⁻, V₁₀O₂₈⁶⁻, C₁₂H₂₅SO₄⁻, and the like.

The tabular inorganic particle layer 3 may be formed by an adsorption method. The adsorption method includes immersing a substrate having a charged surface in a dispersion of particles having a charge opposite to that of the substrate. According to this method, particles are adsorbed on to the substrate surface due to a coulombic force. In an embodiment, the resin film 2, or an intermediate film having a surface of the binder layer 5, is immersed in a dispersion of a tabular inorganic particle having a charge opposite to that of the surface charge of the resin film 2 or the surface charge of the intermediate film. By doing so, the tabular inorganic particle is adsorbed on to the surface of the resin film 2 or the intermediate film. In this regard, the tabular inorganic particle may be adsorbed to be parallel to the surface of the resin film 2 or the intermediate film.

The dispersion of the tabular inorganic particle may be formed by combining an inorganic layered compound and water, followed by stirring. In this regard, a concentration of the inorganic layered compound may be in a range of about 0.01 to about 10 grams per liter (g/L), for example, about 0.1 to about 1 g/L. If the concentration of the inorganic layered compound is too low, the adsorption of the tabular inorganic particle onto the resin film 2 or the intermediate film may be insufficient. Also, if the concentration of the inorganic layered compound is too high, the viscosity of the dispersion may be too high. Although the dispersion is formed from at least water and an inorganic layered compound (in detail, tabular inorganic particles and interlayer ions formed by exfoliation (e.g., layer separation) of the inorganic layered compound), the dispersion may further include a dispersing agent to increase the dispersion of the tabular inorganic particles or an intercalating agent to promote the layer-separation of the inorganic layered compound.

### Structure of the Filling Portion

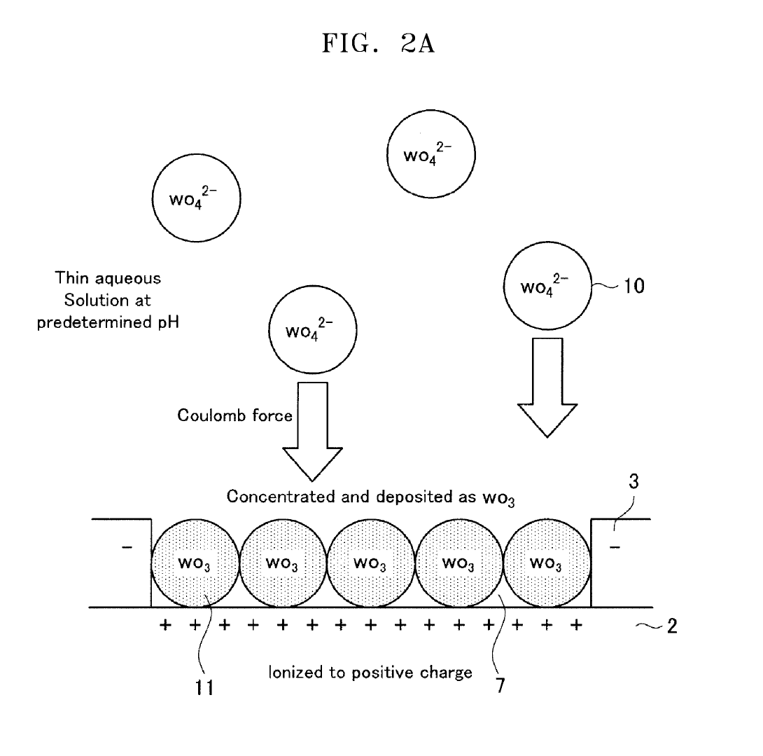

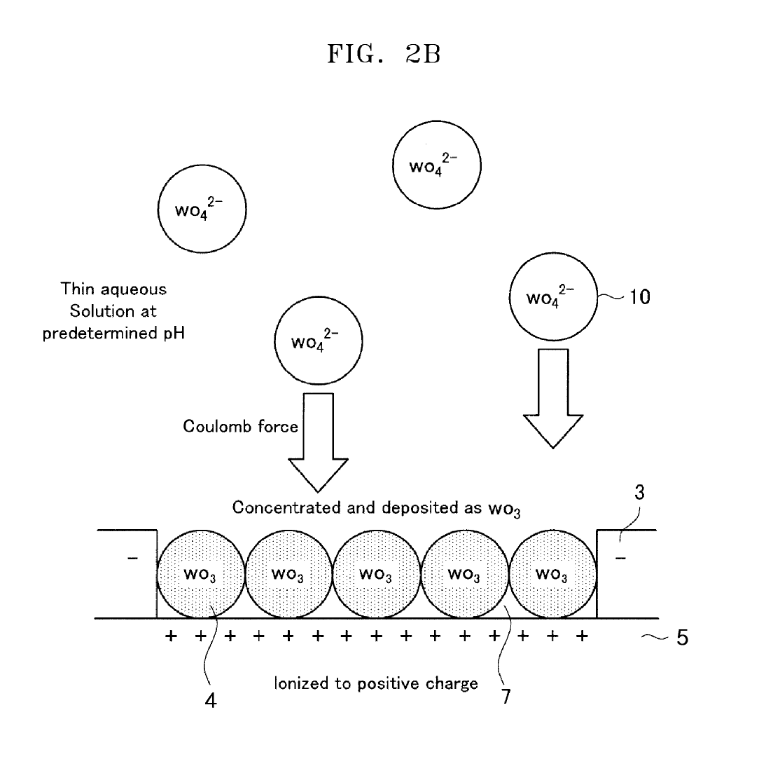

Hereinafter, the structure of a filling portion 4 is further described. As illustrated in FIG. 2A, when the tabular inorganic particle layer 3 is formed by the adsorption method, the tabular inorganic particle layer 3 may include a defect portion 7 where the tabular inorganic particle is not present, e.g., missing. Accordingly, according to an embodiment, the defect portion 7 is filled with the filling portion 4.

The filling portion 4 may include an inorganic material having a low gas permeation rate. As the inorganic material, for example, at least one selected from a metal and a metal oxide may be used.

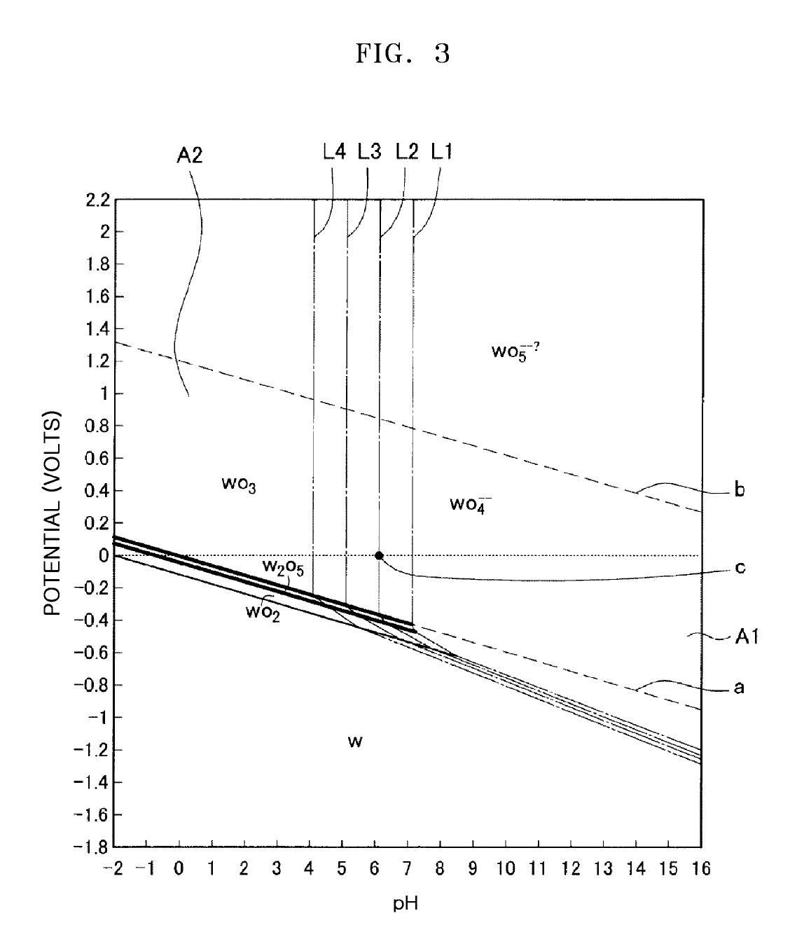

In this regard, an example of a method of filling the defect portion 7 with the filling portion is further described below. In an embodiment, tungsten trioxide (WO₃) was used to form the filling portion 4 that fills the defect portion 7. FIG. 3 is a Pourbaix diagram of tungsten at a temperature of 25° C. A Pourbaix diagram illustrates regions where stable phases of a chemical species (such as a metal) in water are present on a two-dimensional coordinate axis of an electrode potential and a pH. First and second regions A1 and A2, respectively, are interposed between straight line a and straight line b in the Pourbaix diagram and are further described below. The first region A1 is a region in which tungsten exists as a tungstic acid ion (e.g., WO₄²⁻), and the second region A2 is a region in which tungsten exists as tungsten trioxide. A boundary of regions A1 and A2 may be represented by any one of straight lines L1 through L4. That is, when a concentration of tungsten in water is 1 mol/L, the boundary may be the straight line L1; when a concentration of tungsten in water is 1·10⁻² mol/L, the boundary may be the straight line L2; when a concentration of tungsten in water is 1·10⁻⁴ mol/L, the boundary may be the straight line L3; and when a concentration of tungsten in water is 1·10⁻⁶ mol/L, the boundary may be the straight line L4. Also, the boundary belongs to the region A1.

According to this Pourbaix diagram, and while not wanting to be bound by theory, when an electrode potential and a pH are maintained at a constant level, the higher the concentration of tungsten, the wider the region A2 is (that is, tungsten is more likely to precipitate as tungsten trioxide). For example, a point C (e.g., electrode potential=0, and pH=6.0) may belong to the region A1 if the concentration of tungsten is equal to or less than 1·10⁻². Accordingly, when an aqueous solution of tungsten has an electrode potential of 0, a pH of 6.0, and a concentration of 1·10⁻² or less, the tungsten may exist as a tungstic acid ion. Also, the point C may belong to the region A2 if the concentration of tungsten is greater than 1·10⁻². Accordingly, when an aqueous solution of tungsten has an electrode potential of 0, a pH of 6.0, and a concentration of more than 1·10⁻², the tungsten may exist as a tungsten trioxide.

In an embodiment, and while not wanting to be bound by theory, the defect portion 7 is filled with the filling portion 4 based on this principle. That is, first, a tungsten trioxide aqueous solution, for example, an ammonium tungstate, e.g., ((NH₄)WO₄), aqueous solution is prepared. In this regard, the electrode potential (substantially zero), pH, and concentration of the tungsten trioxide aqueous solution are selected such that a point indicating the electrode potential and the pH belongs to the region A1 and is located near the boundary of the region A1 and the region A2. Then, as illustrated in FIGS. 2A and 2B, an intermediate film having a surface of the tabular inorganic particle layer 3 (that is, a film in which the tabular inorganic particle layer 3 is disposed on the surface of the resin film 2, as shown in FIG. 2A, or the binder layer 5 as shown in FIG. 2B, is immersed in the tungsten trioxide aqueous solution. Herein, the resin film 2 or the binder layer 5 is positively charged, and the tabular inorganic particle layer 3 is negatively charged.

While not wanting to be bound by theory, it is understood that a tungstic acid ion 10 in the tungsten aqueous solution is attracted to the defect portion 7 due to a coulombic force, followed by aggregation. By aggregating, the concentration of tungsten in the defect portion 7 is increased and thus, a tungsten trioxide 11 is precipitated in the defect portion 7 to form the filling portion 4. Also, the tungstic acid ion 10 is not disposed on (e.g., aggregated on) a portion of the surface of the resin film 2 or the binder layer 5 where the tabular inorganic particle layer 3 is disposed. This is because the tabular inorganic particle layer 3 is negatively charged.

The metal of the filling portion 4 may be at least one selected from aluminum, iron, magnesium, and potassium. A method of forming the filling portion 4 using the metal is described below. A water-soluble metal compound, for example, a sulfate, a chloride, a hydroxide, or the like is dissolved in water to prepare an aqueous metal solution. In the aqueous metal solution, the metal is present as a cation (e.g., a metal ion). Then, an intermediate film having a surface of the tabular inorganic particle layer 3 is immersed in the aqueous metal solution. In this regard, the tabular inorganic particle layer 3 is positively charged, and the resin film 2 or the binder layer 5 is negatively charged. The metal ion is attracted to the defect portion 7 due to a coulombic force and thus, the metal ion is aggregated in the defect portion 7. While not wanting to be bound by theory, it is understood that by aggregating, the metal ion concentration is increased in the defect portion 7 and thus the metal is precipitated in the defect portion 7 to form the filling portion 4.

Accordingly, an inorganic material of the filling portion 4 may be selected according to the charge of the resin film 2 or the binder layer 5. That is, when the resin film 2 or the binder layer 5 is positively charged, the metal oxide may be used as an inorganic material that constitutes the filling portion 4. This is because the metal oxide is present as an anion (e.g., an oxoacid ion) in an aqueous solution, and a metal oxide ion may be attracted to the defect portion 7 due to a coulombic force. Also, when the resin film 2 or the binder layer 5 is negatively charged, the metal may be used as an inorganic material of the filling portion 4. This is because the metal is present as a cation (e.g., a metal ion) in an aqueous solution, and the metal ion may be attracted to the defect portion 7 by a coulombic force.

When the filling portion 4 comprises aluminum, the metal compound may be at least one selected from AlK(SO₄)₂ and AlNH₄(SO₄)₂. When the filling portion 4 comprises iron, the metal compound may be FeK(SO₄)₂. When the filling portion 4 comprises magnesium, the metal compound may be, for example, at least one selected from MgCl₂ and Mg(NO₃)₂. When the filling portion 4 comprises potassium, the metal compound may be at least one selected from KOH, K₂SO₄, and KCl. A combination comprising at least one of the foregoing can be used.

Also, the metal oxide of the filling portion 4 may be at least one selected from an oxide of vanadium and an oxide of molybdenum, in addition to an oxide of tungsten. The aqueous metal oxide solution may be prepared by dissolving an oxoacid salt of a metal in water. Examples of an oxoacid salt are NaVO₃, (NH₄)₂MoO₄, and (NH₄)₂WO₄. Also, such metal oxides may be a heteropolyacid including phosphorous or silicon. As a metal oxide including phosphorous, for example, H₃PMo₁₂O₄₀.nH₂O (wherein n is a real number greater than 0) may be used, and as a metal oxide including silicon, H₄SiMo₁₂O₄₀.nH₂O (wherein, n is a real number greater than 0) may be used.

### Structure of the Binder Layer

The binder layer 5 may include a binder particle that is ionizable to have a charge opposite to that of the tabular inorganic particle layer 3. Examples of the binder particle are a polymer electrolyte ion, a metal ion, a metal compound ion, and a tabular inorganic particle. The binder layer 5 may include at least one of these materials. In an embodiment, two or more different types of binder particles which have the same charge may be used.

As a polymer electrolyte ion, for example, a polymer electrolyte ion in which a proton is coordinately bonded to a nitrogen atom of a polyarylamine or a polyacrylamide may be used. The metal ion may be an ion of at least one selected from aluminum, magnesium, potassium, and a polyvalent transition metal. The polyvalent transition metal may be at least one selected from iron, cobalt, and manganese. The metal compound ion may be an oxoacid ion of metal, for example, may be at least one selected from VO₃⁻, MoO₄²⁻, WO₄²⁻, TiO²⁺, and the like. A tabular inorganic particle may be obtained by layer-separating the inorganic layered compound described above. For example, when the tabular inorganic particle layer 3 includes a tabular inorganic particle that may be obtained from a clay mineral, the binder layer 5 may include a tabular inorganic particle that may be obtained from a layered double hydroxide compound. Also, when the tabular inorganic particle layer 3 includes a tabular inorganic particle that may be obtained from a layered double hydroxide compound, the binder layer 5 may include a tabular inorganic particle that may be obtained from a clay mineral.

Like the tabular inorganic particle layer 3, the binder layer 5 may be formed by the adsorption method. In an embodiment, the resin film 2, or an intermediate film having a surface of the tabular inorganic particle layer 3, is immersed in an aqueous solution (or dispersion) of an inorganic material that is charged with a charge opposite to the surface of the resin film 2 or the intermediate film. By doing this, the inorganic material is adsorbed on to the surface of the resin film 2 or the intermediate film. That is, the binder layer 5 is formed on the surface of the resin film 2 or the intermediate film. When the inorganic material includes a tabular inorganic particle, the tabular inorganic particle may be adsorbed to have a surface parallel to the surface of the resin film 2 or the intermediate film.

A binder particle aqueous solution (or dispersion) may be obtained by dissolving or dispersing a water-soluble compound or the above-described inorganic layered compound in water. Herein, the concentration of the water-soluble compound or inorganic layered compound may be in a range of about 100 nanomoles per liter (nmol/L) to about 1 mole per liter (mol/L), for example about 1 micromole per liter (μmol/L) to about 100 μmol/L. If the concentration is too low, the adsorption of the binder particle to the resin film 2 or intermediate film may be insufficient. Also, if the concentration is too high, the viscosity of the binder particle aqueous solution (or dispersion) is too high. The binder particle aqueous solution (or dispersion) may include at least water and the binder particle. However, when the binder particle includes the tabular inorganic particle, the binder particle may further include a dispersing agent for increasing the dispersion properties of the tabular inorganic particle or an intercalating agent for promoting the layer separation of the inorganic layered compound particles.

Also, when the binder layer 5 includes a polymer electrolyte ion, the water-soluble compound may be, for example, an ionic polymer, such as at least one selected from polyallylamine hydroxide, polyallylamine hydrochloride, and polyacrylic acid. When the binder layer 5 includes a metal ion, at least one selected from a sulfate, a chloride, and a hydroxide of a metal may be used as a water-soluble compound. For example, at least one selected from AlK(SO₄)₂, AlNH₄(SO₄)₂, MgCl₂, Mg(NO₃)₂, KOH, K₂SO₄, KCl, FeK(SO₄)₂, CoCl₂, Co(NO₃)₂, MnCl₂, Mn(NO₃)₂, NiCl₂, Ni(NO₃)₂, CuCl₂, Cu(NO₃)₂, ZnCl₂, Zn(NO₃)₂, and the like may be used. If the binder layer 5 includes a metal compound ion, a sodium salt or ammonium salt of an oxoacid may be used as the water-soluble compound. For example, at least one selected from NaVO₃, (NH₄)₂MoO₄, (NH₄)₂WO₄, TiOSO₄, and the like may be used.

### Method of Forming the Barrier Film

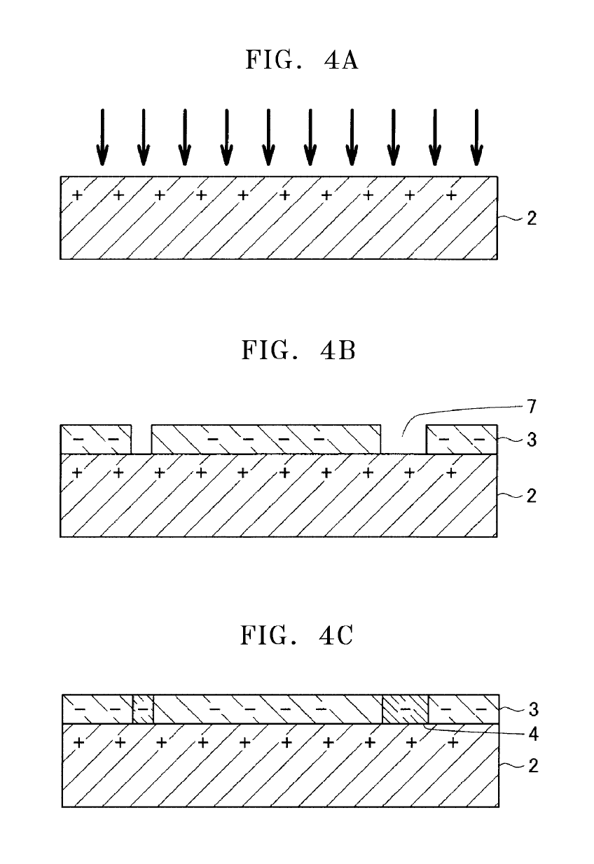

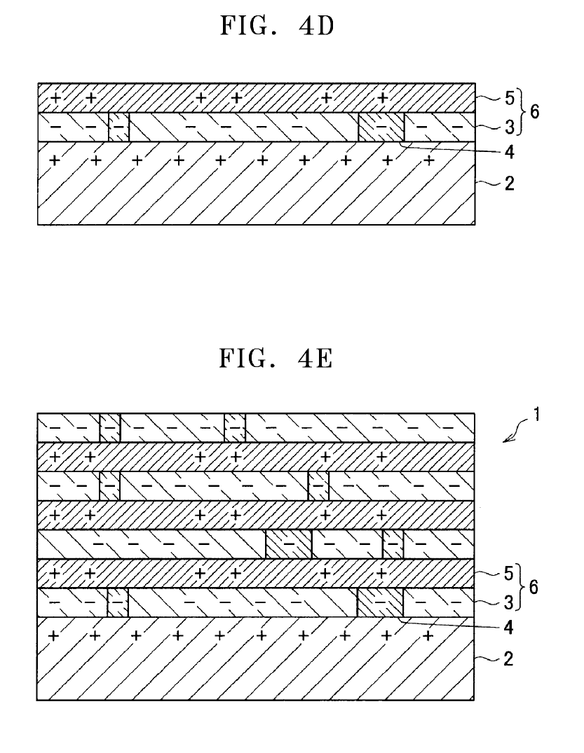

Next, a method of forming the barrier film 1 is further described with reference to FIG. 4. Herein, as an example of the formation method, the tabular inorganic particle layer 3 is disposed on the resin film 2, and then the binder layer 5 is disposed on the tabular inorganic particle layer 3. Alternatively, however, the binder layer 5 may be disposed directly on the resin film 2.

### First Step: Charging of the Resin Film 2

First, as illustrated in FIG. 4A, the surface of the resin film 2 is positively charged. Alternatively, an adsorption layer may be formed on the surface of the resin film 2, and the adsorption layer positively charged. A method of charging the resin film 2 or the adsorption layer may be, for example, a corona treatment, a UV/O₃ treatment, an electron beam (EB) treatment, a chemical treatment using a silane coupling agent, or the like.

### Second Step: Formation of Tabular Inorganic Particle Layer

Then, as illustrated in FIG. 4B, a negatively charged tabular inorganic particle layer 3 is disposed on the surface of the resin film 2. In detail, first, at least one selected from a clay mineral and zirconium phosphate is added to water, followed by stirring to prepare a dispersion of a tabular inorganic particle. Also, the clay mineral and zirconium phosphate has a stack structure in which negatively charged tabular inorganic particles are stacked with an interlayer ion therebetween. Then, the resin film 2 is immersed in a dispersion of the tabular inorganic particle. By doing this, the tabular inorganic particle is adsorbed to the surface of the resin film 2. That is, the tabular inorganic particle layer 3 is formed on the surface of the resin film 2. In this regard, the tabular inorganic particle layer 3 may have the defect portion 7 where the tabular inorganic particle is not present.

### Third Step: Formation of Filling Portion

Then, as illustrated in FIG. 4C, the filling portion 4 is formed (e.g., filled) in the defect portion 7. In detail, the metal oxide is dissolved in water to form an aqueous metal oxide solution. The aqueous metal oxide solution may include an oxoacid ion (an anion). Herein, in a Pourbaix diagram of the metal oxide, the electrode potential (substantially zero), pH, and concentration of the metal oxide aqueous solution may be selected such that the point of the selected electrode potential and a pH belongs to an ionic region (i.e., the region corresponding to the region A1 of FIG. 3) and is located near the boundary of the ionic region and a solid region (i.e., the region corresponding to the region A2 of FIG. 3).

Then, an intermediate film having a surface of the tabular inorganic particle layer 3 is immersed in the metal oxide aqueous solution. By doing this, an oxoacid ion in the metal oxide aqueous solution may be attracted by the defect portion 7 due to a coulombic force, followed by aggregation. In this manner a concentration of the oxoacid ion in the defect portion 7 is increased and thus, the metal oxide precipitates in the defect portion 7, thereby forming the filling portion 4. Also, in a portion of the surface of the resin film 2 on which the tabular inorganic particle layer 3 is formed, an oxoacid ion is not aggregated. While not wanting to be bound by theory, it is understood that this is because the tabular inorganic particle layer 3 is negatively charged.

### Fourth Step: Formation of Binder Layer

Then, as illustrated in FIG. 4D, the binder layer 5 is disposed on the tabular inorganic particle layer 3. For example, first, an aqueous binder particle solution (or dispersion), in which at least one selected from a positively charged polymer electrolyte ion, a positively charged metal ion, a positively charged metal compound ion, and a positively charged tabular inorganic particle is dissolved (or dispersed) is prepared. Then, an intermediate film having a surface of the tabular inorganic particle layer 3 is immersed in the aqueous binder particle solution (or dispersion). While not wanting to be bound by theory, it is understood that by contacting the tabular inorganic particle 3 and the binder particle, the binder particle is adsorbed on to the surface of the intermediate film. That is, the binder layer 5 is formed on the surface of the intermediate film. In this regard, when the binder particle includes a tabular inorganic particle, the tabular inorganic particle may be adsorbed to have a surface parallel to the surface of the intermediate film.

### Fifth Step: Repetition

Then, as shown in FIG. 4E, the second through fourth steps are repeatedly performed to alternately dispose the tabular inorganic particle layer 3 and the binder layer 5 on the resin film 2. A pair of the tabular inorganic particle layer 3 and the binder layer 5 constitutes a unit 6, thereby completing the formation of the barrier film 1. The barrier film may comprise any number of units, specifically 1 to about 100 units, more specifically 2 to 50 units.

### Operation of the Barrier Film

Then, referring to FIG. 1, operation of the barrier film 1 is further described. If a gas, such as water vapor or oxygen gas, arrives at the tabular inorganic particle layer 3 after passing through the resin film 2, the gas may not pass through the tabular inorganic particle included in the tabular inorganic particle layer 3. Accordingly, the gas may diffuse through a permeation pathway 100 illustrated in FIG. 1. The gas permeation into the barrier film 1 may be classified as, as represented by Equation (1) below, permeation into the binder layer 5 and permeation into the filling portion 4.

1/T=1/Tb+1/Tp (Equation 1)

### In Equation 1,

T is a gas permeation rate of the entire barrier film 1;

Tb is a gas permeation rate of the entire binder layer 5; and

Tp is a gas permeation rate of the entire filling portion 4.

A gas permeation rate of the entire binder layer 5 is proportional to a length of a gas permeation pathway in the binder layer 5, a gas permeation rate per a unit length (e.g., unit thickness) of the binder layer 5, and an area of a permeation cross-section of the binder layer 5 (e.g., a cross section perpendicular to the permeation pathway 100). The area of a permeation cross-section of the binder layer 5 is proportional to a film thickness of the binder layer 5. Accordingly, the gas permeation rate of the entire binder layer 5 may be represented by Equation (2).

Tb∝L*Tb0*Db (Equation 2)

### In Equation 2,

Tb is a gas permeation rate of the entire binder layer 5;

L is a length of a gas permeation pathway in the binder layer 5;

Tb0 is a gas permeation rate per a unit length (e.g., unit thickness) of the binder layer 5; and

Db is a film thickness of the binder layer 5 (for example, an arithmetic mean value of thicknesses of the respective binder layers 5, wherein the film thickness is measured by, for example, an ellipsometer, AFM, or the like).

Also, a gas permeation rate of the entire filling portion 4 may be proportional to a thickness of the filling portion 4, a gas permeation rate per a unit length (e.g., unit thickness) of the filling portion 4, and an area of a permeation cross-section of the defect portion 7 (e.g., a cross section perpendicular to the permeation pathway 100). The gas permeation rate of the entire filling portion 4 may be represented by Equation (3) below.

Tp∝Dp*Tp0*Sc (Equation 3)

### In Equation 3,

Tp is a gas permeation rate of the entire filling portion 4;

Dp is a film thickness of the filling portion 4 (for example, an arithmetic mean value of film thicknesses of the respective filling portions 4);

Tp0 is a gas permeation rate of the filling portion 4 per unit length (e.g., unit thickness); and

Sc is an area of the permeation cross-section of the defect portion 7.

According to the technology disclosed in patent literature 1, nothing is provided to the defect portion of the clay layer, and thus, Tp0 of Equation 3 would have a very high value. That is, Tp would have a very high value, and as a result, T is increased. However, in the case of the barrier film 1, because the defect portion 7 of the tabular inorganic particle layer 3 is filled with the filling portion 4, that is, an inorganic material, Tp0 may have a small value, and as a result, Tp is decreased and thus, a gas permeation rate T of the entire barrier film 1 may be reduced. Accordingly, the barrier film 1 may reduce a gas permeation rate (that is, improve barrier performance) compared to the technology disclosed in the patent literature 1. Also, because the barrier film 1 may have a relatively small number of layer-by-layer adsorptions (e.g., a small number of units 6) compared to typical films, a process may be simplified.

Also, in an embodiment, the binder layer 5 is formed by an adsorption method. Accordingly, compared to the technology disclosed in the reference literature 2, Db is very small. For example, Example 2 of the reference literature 2 discloses that 10 mass % of an inorganic layered compound formed from expandable synthetic mica is dispersed in 3 μm of a sol-gel material. It is assumed that in Example 2 of the reference literature 2, an arithmetic mean interval between the inorganic layered compounds is about 300 nm. However, regarding the barrier film 1, a film thickness of the binder layer 5 is 1 nm or less, and thus, Db is two or more orders of magnitude smaller. Also, when the binder layer 5 includes the inorganic layered compound disclosed in the reference literature 2, Tb is at an equivalent level. Accordingly, the barrier film 1 has higher barrier performance than when the technology disclosed in the reference literature 2 is used.

Also, in the barrier film 1, instead of directly using a water-susceptible (that is, expandable due to water) inorganic layered compound as the tabular inorganic material layer 3, an inorganic layered compound is layer-separated to form a tabular inorganic particle, and the tabular inorganic particle is used to form the tabular inorganic particle layer 3. In detail, in an embodiment of the barrier film 1, an inorganic layered compound is added to water, followed by stirring to layer-separate (e.g., exfoliate) the inorganic layered compound. Also, the resulting tabular inorganic particle is adsorbed on to the resin film 2 or the binder layer 5 by the ion adsorption method to form the tabular inorganic particle layer 3. By adsorbing the tabular inorganic particle on to the resin film 2 or the binder layer 5, in the barrier film 1 for an electronic device, expansion of the tabular inorganic material layer 3 due to the permeation of gas, such as water vapor, into the tabular inorganic material layer 3 may be substantially or effectively prevented. Also, in the barrier film 1, because a tabular inorganic particle is adsorbed on to other layers by a coulombic force, permeation of a gas, such as water vapor, between the tabular inorganic particle layer 3 and other layers, may also be substantially or effectively prevented. Accordingly, the barrier film 1 may have improved barrier performance as compared to that disclosed in the reference literature 1.

Hereinafter, the disclosed embodiments are further described with reference to Examples below. However, the present disclosure is not limited to the Examples.

### EXAMPLES

### Example 1

In the present experiment, the resin film 2 was positively charged, and the negatively charged tabular inorganic particle layer 3 and the positively charged binder layer 5 were alternately disposed on the resin film 2.

### 1) Washing of Resin Film 2

A PET film having a thickness of 0.1 mm was prepared as the resin film 2. The resin film 2 was washed with a detergent and pure water and dried by using an air blower.

### 2) Preparation of Tabular Inorganic Particle Dispersion

0.5 grams (g) of Kunipil-D 36, which is a product of Kuminine industry and is a montmorillonite (MMT) was added to 1 liter (L) of pure water, and stirred by using a commercially available agitator (KNS-T1, a product of Azwon) for one day. By doing this, a tabular inorganic particle dispersion in which a tabular inorganic particle was dispersed was prepared.

### 3) Preparation of Aqueous Binder Particle Solution

An aqueous solution including 30 millimoles per liter (mmol/L) of polyallylamine hydroxide (PAH) was prepared.

### 4) Preparation of Aqueous Filling Portion Solution

An aqueous solution including 1 mmol/L of NaVO₃ was prepared and a pH thereof was measured. The pH was 5.9. The pH of the aqueous solution was adjusted to 6.5 by adding aqueous NaOH (having a concentration of 100 mmol/L) thereto, thereby completing the preparation of an aqueous filling portion solution.

### 5) Charging of Resin Film 2

The resin film 2 washed in the process 1) was immersed in an ethanol solution including 10 mmol/L of 3-aminopropyltriethoxysilane (APTES) for 30 minutes. Thereafter, the resin film 2 was washed with ethanol and pure water and dried using an air blower. By doing this, the resin film 2 was positively charged.

### 6) Formation of the Tabular Inorganic Particle Layer

The resin film 2 charged in the process 5) was immersed in the tabular inorganic particle dispersion prepared in the process 2) for 15 minutes, and then sufficiently washed with pure water, and dried using an air blower. By doing this, the tabular inorganic particle layer 3 was formed on the surface of the resin film 2.

### 7) Formation of Filling Portion

The resin film 2 on which the tabular inorganic particle layer 3 was formed, prepared in the process 6), was immersed in the aqueous filling portion solution prepared in the process 6) for 15 minutes, and then sufficiently washed with pure water, and dried by using an air blower. By doing this, the filling portion 4 was formed in the defect portion 7 of the tabular inorganic particle layer 3.

### 8) Formation of Binder Layer

The resin film 2 on which the tabular inorganic particle layer 3 and the filling portion 4 was formed, prepared in the process 7) was immersed in the aqueous binder particle solution prepared in the process 3) for 15 minutes, and then sufficiently washed with pure water, and dried using an air blower. By doing this, the binder layer 5 was formed on the tabular inorganic particle layer 3.

### 9) Layer-by-Layer Adsorption

The processes 6) to 8) were repeatedly performed 5, 10, and 20 times to form three barrier films 1 having 5, 10, or 20 units 6 (i.e., a pair of the tabular inorganic particle layer 3 and the binder layer 5) formed on the resin film 2.

### 10) WVTR Measurement

A WVTR of each of the three barrier films 1 prepared from the process 9) was measured using a water vapor transmission measurement device AQUATRAN, which is a product of MOCON.

### Example 2

This experiment was different from Example 1 in the filling portion 4. That is, this experiment was the same as Example 1, except that step 4) of Example 1 was changed as below and three barrier films 1 were formed and WVTRs thereof were measured.

### 4) Preparation of the Aqueous Filling Portion Solution

An aqueous solution including 1 mmol/L of (NH₄)₂WO₄ was prepared and a pH thereof was measured. The pH was 5.5. The pH of the aqueous solution was adjusted to be 6.0 by adding aqueous NaOH (having a concentration of 100 mmol/L) thereto to prepare an aqueous filling portion solution.

### Example 3

This experiment was different from Example 1 in the filling portion 4. That is, this experiment was the same as Example 1, except that 4) of Example 1 was changed as below and three barrier films 1 were formed and WVTRs thereof were measured.

### 4) Preparation of the Aqueous Filling Portion Solution

An aqueous solution including 1 mmol/L of (NH₄)₂MoO₄ was prepared and a pH thereof was measured. The pH was 5.0. The pH of the aqueous solution was adjusted to be 4.0 by adding aqueous HCl (having a concentration of 100 mmol/L) thereto to prepare an aqueous filling portion solution.

### Example 4

In the present experiment, the resin film 2 was negatively charged, and the positively charged tabular inorganic particle layer 3 and the negatively charged binder layer 5 were alternately disposed on the resin film 2.

### 1) Washing of Resin Film 2

A PET film having a thickness of 0.1 mm was prepared as the resin film 2. The resin film 2 was washed with a detergent and pure water and dried by using an air blower.

### 2) Preparation of Tabular Inorganic Particle Dispersion

20 m L of a mixed aqueous solution including 1 mol/L of sodium chloride, 0.01 mol/L of an acetic acid, and 0.09 mol/L of a sodium acetate was added to 20 mg of a layered double hydroxide (LDH) compound prepared from M²⁺ₓM³⁺_{y}(OH)ₙCO₃.nH₂O (M²⁺: Mg, M³⁺: Al, B: CO₃²⁻, x=4.5, y=2, n=13), followed by 2 days of stirring by a commercially available agitator (SH-B type Terasawa) to prepare a tabular inorganic particle dispersion in which a LDH formed from M²⁺ₓM³⁺_{y}(OH)ₙCl₂.nH₂O (M²⁺: Mg, M³⁺: Al, B: CO₃²⁻, x=4.5, y=2, n=13) was dispersed.

### 3) Preparation of Binder Particle Aqueous Solution

An aqueous solution including 30 mmol/L of a polyacrylic acid (PAA) was prepared as a binder particle aqueous solution.

### 4) Preparation of the Aqueous Filling Portion Solution

An aqueous solution including 30 mmol/L of AlK(SO₄)₂ was prepared as a filling portion aqueous solution.

### 5) Charging of Resin Film 2

The resin film 2 washed in the process 1) was subjected to a corona treatment using HPS-101, which is a product of STATIC Company, Japan, for 10 minutes.

### 6) Formation of Tabular Inorganic Particle Layer

The resin film 2 charged in the process 5) was immersed in the tabular inorganic particle dispersion prepared in the process 2) for 15 minutes, and then sufficiently washed with pure water, and dried by using an air blower. By doing this, the tabular inorganic particle layer 3 was formed.

### 7) Formation of the Filling Portion

The resin film 2 on which the tabular inorganic particle layer 3 was disposed, prepared in the process 6) was immersed in the aqueous filling portion solution prepared in the process 4) for 15 minutes, and then sufficiently washed with pure water, and dried by using an air blower. By doing this, the filling portion 4 was disposed in the defect portion 7 of the tabular inorganic particle layer 3.

### 8) Formation of Binder Layer

The resin film 2 on which the tabular inorganic particle layer 3 and the filling portion 4 was formed, prepared in the process 7) was immersed in the binder particle aqueous solution prepared in the process 3) for 15 minutes, and then sufficiently washed with pure water, and dried by using an air blower. By doing this, the binder layer 5 was formed.

### 9) Layer-by-Layer Adsorption

The processes 6) to 8) were repeatedly performed 5, 10, and 20 times to form three barrier films 1 having 5, 10, or 20 units 6 (a pair of the tabular inorganic particle layer 3 and the binder layer 5) formed on the resin film 2.

### 10) WVTR Measurement

A WVTR of the three barrier films 1 prepared from the process 9) was measured using a water vapor transmission measurement device AQUATRAN, which is a product of MOCON.

### Example 5

This experiment is different from Example 1 in the formation of an adsorption layer. In detail, this experiment is the same as Example 1, except that 5) of Example 1 was changed as below and three barrier films 1 were formed and WVTRs thereof were measured.

### 5) Charging of Resin Film 2

Akuamika NL100A, which is a product of AZ Electronic Materials Company, was spin coated on the resin film 2 washed in the process 1) using MS-A150, which is a product of Mikasa Company. Then, the resin film 2 was cured at a temperature of 120° C. for 1 hour, and subsequently treated at a temperature of 95° C. and a humidity of 80% for 3 hours. By doing this, a silica layer having a thickness of about 0.2 μm was formed as an adsorption layer on the surface of the resin film 2. The resin film 2 was immersed in an ethanol solution including 10 mmol/L of 3-aminopropyltriethoxysilane (APTES) for 30 minutes. Thereafter, the resin film 2 was washed with ethanol and pure water and dried by using an air blower. By doing this, the silica layer was positively charged.

### Comparative Example 1

Three comparative films were formed using the same process as in Example 1, except that the processes 4) and 7) of Example 1 were not performed, and WVTRs thereof were measured.

[WVTR Measurement Results]

WVTRs (unit: g/m²/day) of the barrier films 1 Examples 1 to 5 and the comparative film prepared according to Comparative Example 1 were measured at a temperature of 40° C. and a humidity of 90% RH. Results thereof are shown in Table 1 below.

TABLE 1

| | | WVTR(g/m²/day) | | | | | |
|---|---|---|---|---|---|---|---|
| | | | | | | | Comparative |
| | | Example 1 | Example 2 | Example 3 | Example 4 | Example 5 | Example 1 |
| Charging | | APTES | APTES | APTES | Corona | APTES | APTES |
| treatment | | | | | | | |
| Tabular | | MMT | MMT | MMT | LDH | MMT | MMT |
| inorganic | | | | | | | |
| particle layer | | | | | | | |
| Binder layer | | PAH | PAH | PAH | PAA | PAH | PAH |
| Aqueous | | NaVO₃ | (NH₄)₂WO₄ | (NH₄)₂MoO₄ | AlK(SO₄)₂ | NaVO₃ | None |
| filling portion | | | | | | | |
| solution | | | | | | | |
| Stack | 5 | 0.0520 | 0.0468 | 0.0550 | 0.0494 | 0.0159 | 0.8526 |
| number | 10 | 0.0261 | 0.0240 | 0.0269 | 0.0190 | 0.0080 | 0.3115 |
| (pair) | 20 | 0.0139 | 0.0129 | 0.0143 | 0.0103 | 0.0040 | 0.1551 |

The WVTRs of the barrier films 1 prepared according to Examples 1-5 were smaller than that of the comparative film of Comparative Example 1. This result shows that the barrier film 1 for an electronic device according to the present embodiment has a higher barrier performance than that of the comparative film of Comparative Example 1. For example, to obtain the range of 10⁻² g/m²/day WVTR, even with 20 pairs of layer-by-layer adsorption (that is, 20 units) as in Comparative Example 1, such WVTR values were obtained. However, in Examples 1-5, such WVTR values were provided with only 5 pairs of the layer-by-layer adsorption (that is, 5 units 6). That is, it was confirmed that the barrier film 1 formed using the layer-by-layer adsorption according to the present embodiment provides higher performance with a smaller stack number than a barrier film formed using layer-by-layer adsorption but not having the filling portion.

Also, while not wanting to be bound by theory, it is understood that the reason that the WVTR of the barrier film 1 of Example 5 is smaller than the WVTR of the barrier film 1 of Example 1 may be due to the fact that the charging effect was increased by the formation of the silica layer formed according to Example 5 so that the tabular inorganic particle layer 3 was more fully adsorbed to the resin film 2.

As is further described above, in the barrier film 1 for an electronic device, the defect portion 7 is filled with the filling portion 4. Due to the filling portion 4, the permeation of gas through the defect portion 7 may be substantially or effectively prevented. Accordingly, the barrier film 1 may have improved barrier performance.

A barrier film for an electronic device includes a filling portion that fills a defect portion. Due to the filling portion, the permeation of gas into the defect portion may be substantially or effectively prevented. Accordingly, the barrier film may have improved barrier performance.

It should be understood that the exemplary embodiments described herein should be considered in a descriptive sense only and not for purposes of limitation. Descriptions of features, advantages or aspects within each embodiment should be considered as available for other similar features, advantages, or aspects in other embodiments.

What is claimed is:

1. A barrier film for an electronic device, the barrier film comprising:
a resin film;
a layer-by-layer stack portion comprising a tabular inorganic particle layer and a binder layer which are alternately disposed on the resin film and are oppositely charged; and
a filling portion that fills a defect portion of the tabular inorganic particle layer wherein the defect portion is a portion of the tabular inorganic particle layer where a tabular inorganic particle of the tabular inorganic particle layer is not present.

2. The barrier film of claim 1, wherein the filling portion comprises a metal oxide.

3. The barrier film of claim 2, wherein the metal oxide comprises at least one metal selected from vanadium, tungsten, and molybdenum.

4. The barrier film of claim 2, wherein the metal oxide comprises phosphorus.

5. The barrier film of claim 1, wherein the tabular inorganic particle of the tabular inorganic particle layer is negatively charged and the binder layer is positively charged.

6. The barrier film of claim 1, wherein the tabular inorganic particle is an exfoliation product of at least one selected from a clay mineral and zirconium phosphate.

7. The barrier film of claim 6, wherein the clay mineral comprises at least one selected from mica, bermiculite, montmorillonite, iron montmorillonite, beidellite, saponite, hectorite, and stevensite.

8. The barrier film of claim 7, wherein the clay mineral comprises montmorillonite.

9. The barrier film of claim 6, wherein the tabular inorganic particle is an exfoliation product of zirconium phosphate.

10. The barrier film of claim 1, further comprising an adsorption layer disposed on the resin film and which adsorbs the resin film to the layer-by-layer stack portion.

11. The barrier film of claim 10, wherein the adsorption layer comprises at least one selected from silica and alumina.

12. The barrier film of claim 10, wherein the adsorption layer has a charge opposite to that of a charge of a layer of the layer-by-layer stack portion adsorbed on the adsorption layer.

13. The barrier film of claim 12, wherein the adsorption layer is charged by contacting with a silane coupling agent.

14. A method of manufacturing a barrier film for an electronic device, the method comprising:
providing a resin film having a charged surface;
disposing a charged tabular inorganic particle on the resin film to form a tabular inorganic particle layer;
contacting the tabular inorganic particle layer with a solution comprising at least one selected from a metal and a metal oxide to fill a defect of the tabular inorganic particle layer and form a filled tabular inorganic particle layer; and
contacting the filled tabular inorganic particle layer with a charged binder particle to form a binder layer on the filled tabular inorganic particle layer and manufacture the barrier film.

15. The method of claim 14, further comprising repeating the disposing of the charged tabular inorganic particle, the contacting the tabular inorganic particle layer with a solution, and the contacting the filled tabular inorganic particle layer with a charged binder particle to form an additional filled tabular inorganic particle layer and an additional binder layer on the binder layer.

16. The method of claim 14, wherein the resin film is charged by corona treatment, UV/O₃ treatment, electron beam treatment, or contacting with a silane coupling agent.

17. The method of claim 14, wherein the charged tabular inorganic particle is an exfoliation product of at least one selected from a clay mineral selected from mica, bermiculite, montmorillonite, iron montmorillonite, beidellite, saponite, hectorite, and stevensite; zirconium phosphate; and a layered double hydroxide compound.

18. The method of claim 14, wherein the solution comprising at least one selected from a metal and a metal oxide is an aqueous solution of a sodium salt or an ammonium salt of an oxoacid of at least one selected from vanadium, molybdenum, and tungsten.

19. The method of claim 14, wherein the contacting the filled tabular inorganic particle layer with a charged binder particle comprises contacting with a solution comprising at least one selected from polyallylamine hydroxide, polyallylamine hydrochloride, and polyacrylic acid.

20. The method of claim 14, wherein the contacting the filled tabular inorganic particle layer with a charged binder particle comprises contacting with a solution comprising at least one selected from AlK(SO₄)₂, AlNH₄(SO₄)₂, MgCl₂, Mg(NO₃)₂, KOH, K₂SO₄, KCl, FeK(SO₄)₂, CoCl₂, Co(NO₃)₂, MnCl₂, Mn(NO₃)₂, NiCl₂, Ni(NO₃)₂, CuCl₂, Cu(NO₃)₂, ZnCl₂, Zn(NO₃)₂, NaVO₃, (NH₄)₂MoO₄, (NH₄)₂WO₄, and TiOSO₄.
